(19) United States
(12) Patent Application Publication
(10) Pub. No.: US 2026/0206383 A1
(43) Pub. Date: Jul. 16, 2026

(54) DISPLAY HAVING GRADIENT MIXED MICRO-LED CHIPS

(71) Applicant: RAYLEIGH VISION INTELLIGENCE CO., LTD., Hsinchu City (TW)

(72) Inventor: Chia-Jung LIN, Hsinchu City (TW)

(21) Appl. No.: 19/448,973

(22) Filed: Jan. 14, 2026

(30) Foreign Application Priority Data
Jan. 16, 2025 (TW) 114101767

(51) Int. Cl. H10H 29/24

(52) U.S. Cl. CPC H10H 29/24

(57) ABSTRACT

The display having gradient mixed micro-LED chips is provided. The display comprises a substrate and a plurality of micro-LED chips. The substrate comprises at least one main region, wherein the at least one main region comprises a plurality of sub regions which are arranged along a first direction. Each of the sub regions extends along a second direction perpendicular to the first direction. The plurality of micro-LED chips respectively attributed to a plurality of groups according to a plurality of grades in an optical characteristic. The plurality of chip groups are respectively disposed within the plurality of sub regions based on the sequence of the plurality of grades.

### CROSS-REFERENCE TO RELATED APPLICATION

This application claims priority from Taiwan Patent Application No. 114101767 filed on Jan. 16, 2025, which are hereby incorporated herein by reference in its entirety.

### BACKGROUND OF THE INVENTION

### 1. Field of the Invention

The present disclosure pertains to a display incorporating Micro-LED chips that are gradient mixed. More specifically, it relates to a display in which the Micro-LED chips are arranged according to a defined pattern based on die bin classifications.

### 2. Description of Related Art

In the field of light-emitting diode (LED) technology, advancements have led to the miniaturization of conventional LEDs to the micrometer scale, resulting in what are known as micro-LEDs (Micro-LED, μLED). When applied to display technology, each micro-LED functions as a sub-pixel within a display panel, forming what is referred to as a micro-LED display. Owing to their high luminous efficiency, long lifespan, and ability to deliver high resolution, micro-LED displays are widely regarded as a leading candidate for next-generation display technology.

The epitaxial process for micro-LEDs typically uses techniques such as metal organic chemical vapor deposition (MOCVD) to grow the light-emitting structure layers on a support substrate. Before the individual completed light-emitting units (i.e., single micro-LED chips) are applied to products with lighting or display functions, each unit needs to be tested to establish data for chip grading or binning, such as brightness, wavelength, or driving current. The data is then used by the mass transfer equipment to place the binned or graded micro-LEDs onto a target substrate at high speed.

The application of micro-LED displays is becoming increasingly widespread, and therefore the requirements for the uniformity of brightness or color differences of micro-LED chips used in the displays are also increasing, especially for the requirement that there should be no color difference in small areas of the display. As a result, after testing, some micro-LED chips of certain grades or bins cannot be used, leading to a low yield rate and a significant increase in production costs. On the other hand, to use most of the chips of various grades or bins, a random method is employed to place the chips of different grades or bins on the display substrate, which includes the drive circuit. However, this random mixing of chips can easily cause the maximum difference in brightness or color between adjacent pixels, making it easy to see specks in the image.

### SUMMARY OF THE INVENTION

In one embodiment of the present disclosure, a display with gradient mixed micro-LED chips comprises: a substrate comprising at least one main region, wherein the at least one main region comprises a plurality of sub regions arranged along a first direction, and each of the sub regions extends along a second direction perpendicular to the first direction; and a plurality of micro-LED chips respectively attributed to a plurality of chip groups according to a plurality of grades in an optical characteristic, wherein the plurality of chip groups are respectively disposed within the plurality of sub regions based on a sequence of the plurality of grades.

In another embodiment of the present disclosure, the at least one main region includes a first main region and a second main region, wherein the plurality of chip groups are arranged in the sub regions of the first main region in an increasing order of the plurality of grades along the first direction and in the sub regions of the second main region in a decreasing order of the plurality of grades along the first direction.

In yet another embodiment of the present disclosure, the at least one main region includes a first main region and a second main region, wherein the plurality of chip groups are arranged in the plurality of sub regions of the first main region in a decreasing order of the plurality of grades along the first direction, and the plurality of chip groups are arranged in the plurality of sub regions of the second main region in an increasing order of the plurality of grades along the first direction.

In another embodiment of the present disclosure, the first main region and the second main region have the same area.

In yet another embodiment of the present disclosure, the plurality of sub regions have the same area.

In another embodiment of the present disclosure, the optical characteristic includes brightness or wavelength range.

In another embodiment of the present disclosure, a display with a gradient mixed micro-LED chips comprises: a substrate comprising at least one main region, wherein the at least one main region comprises a plurality of sub regions arranged along a first direction, and each of the sub regions extends along a second direction perpendicular to the first direction, and each of the sub regions includes a plurality of child regions arranged in an array; and a plurality of micro-LED chips respectively attributed to a plurality of chip groups according to a plurality of grades in an optical or electrical characteristic, wherein the plurality of chip groups are regularly arranged in the child regions of the plurality of sub regions; wherein in the child regions of the sub region closest to a starting point of the first direction, a part of the micro-LED chips are arranged in a manner that their grades increase along the first direction and decrease along the second direction; and wherein in the child regions of the next sub region adjacent to the previous sub region along the first direction, another part of the micro-LED chips are arranged and the another part includes a latter relative maximum grade and a later relative minimum grade; wherein the later relative maximum grade is greater than a former relative maximum grade in the previous sub region, and the micro-LED chip with the latter relative maximum grade is disposed at an identical location of the next child region as the micro-LED chip with the former relative minimum grade in the previous sub region.

In another embodiment of the present disclosure, the grades of the other micro-LED chips in the previous and next sub regions and a rule for their arrangement are the same.

In another embodiment of the present disclosure, the electrical characteristic is a drive current.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIG. 1 is a schematic diagram of a display with gradient mixed micro-LED chips according to one embodiment of the present disclosure.

FIGS. 2A to 2D are schematic diagrams illustrating the arrangement of micro-LED chips of different grades in each sub region according to the embodiment of FIG. 1.

FIG. 3 is a schematic diagram of a display with gradient mixed micro-LED chips according to another embodiment of the present disclosure.

FIG. 4 is a schematic diagram of a display with gradient mixed micro-LED chips according to yet another embodiment of the present disclosure.

FIGS. 5A to 5E are schematic diagrams illustrating the child regions within each sub region according to the embodiment of FIG. 4.

FIGS. 6A to 6E are schematic diagrams showing the regular arrangement of micro-LED chips with various grades within the child regions of each sub region as depicted in FIGS. 5A to 5E.

### DETAILED DESCRIPTION OF THE INVENTION

The following description shows the various embodiments of the present invention. The present invention is described below by referring to the embodiments and the figures. Thus, the present invention is not intended to be limited to the embodiments shown but is to be accorded the principles disclosed herein. Furthermore, various modifications or changes in light thereof will be suggested to a person skilled in the art and are to be included within the spirit and purview of this application and scope of the appended claims.

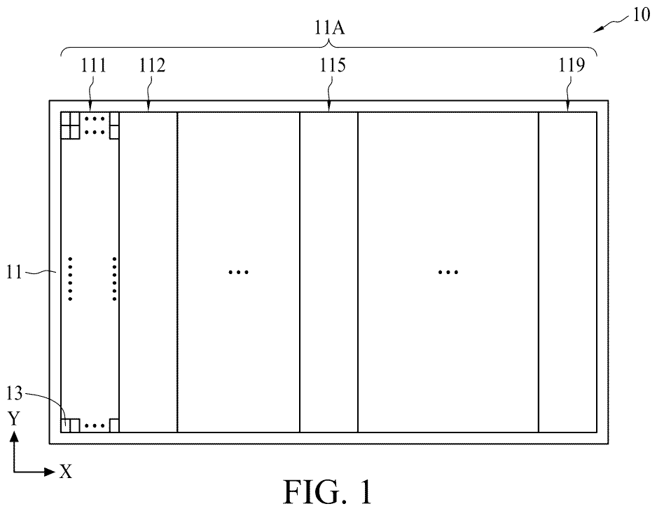

FIG. 1 depicts a schematic diagram of a display with a gradient mixed micro-LED chips according to one embodiment of the present disclosure. The display 10 can have a maximum resolution of 1,920×1,080 pixels or other specifications, which includes a substrate 11 (such as a display substrate containing a driving circuit) and a plurality of micro-LED chips 13. In this embodiment, the substrate 11 includes a main region 11A. The main region 11A comprises a plurality of sub regions 111 to 119 which are arranged along a first direction (the X-axis), and each of them extends along a second direction (the Y-axis) perpendicular to the first direction. After undergoing optical and electrical performance tests, the plurality of micro-LED chips 13 can be categorized into multiple groups based on their optical or electrical characteristics, such as bin 1 to bin 9, which represent the brightness levels of the RGB micro-LED chips. The bins can be arranged in ascending or descending order of brightness. The multiple groups of chips (e.g., bin 1 to bin 9) are placed in different sub regions 111-119 according to their respective grades.

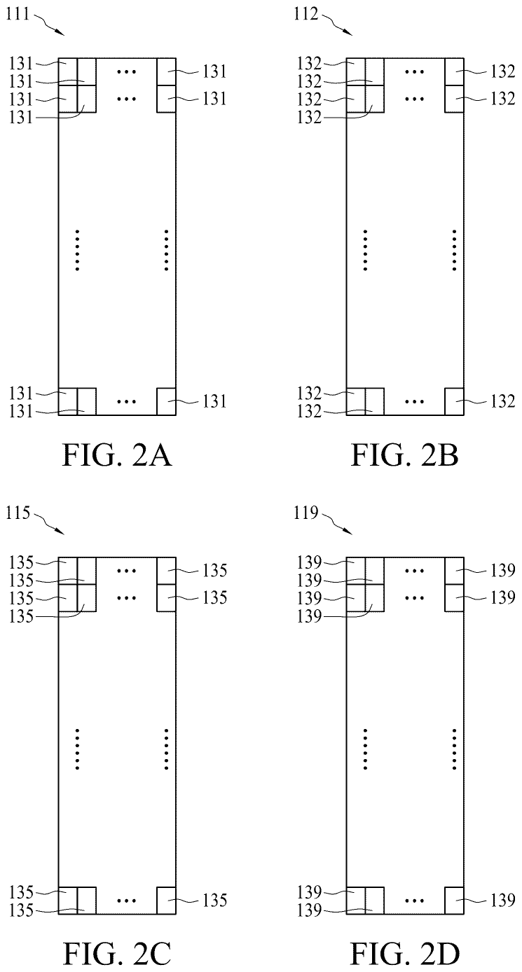

Referring to FIGS. 2A to 2D, as shown in the embodiment of FIG. 1, the chips 131-139 with different grades are disposed within each of the sub regions 111-119. These chips 131-139 with different grades respectively belong to the foregoing multiple groups (e.g., bin 1 to bin 9). In this embodiment, the micro-LED chips 13 in each of the sub regions 111-119 are of the same grade.

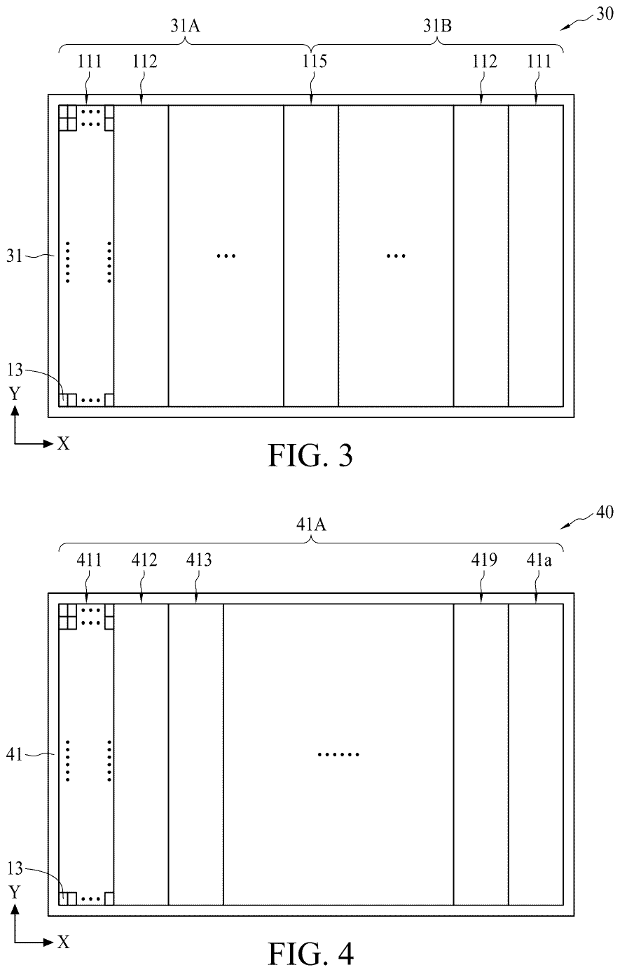

In comparison with the embodiment shown in FIG. 1, the substrate 31 of the embodiment shown in FIG. 3 includes two main regions, namely the first main region 31A and the second main region 31B, which can have the same area. The first main region 31A includes the sub regions 111-114 and half of the sub region 115 (in another embodiment, it can be the entire s ub region 115) in the first direction (X-axis direction). The second main region 31B includes the other half of the sub region 115 (or the entire secondary region 115 in another embodiment) and the sub regions 114-111 in the first direction. In other words, in this embodiment, multiple chip groups (e.g., bin 1 to bin 5) are arranged in the first main region 31A along the first direction in the order of increasing grade (1 to 5), and in the second main region 31B, they are arranged in the order of decreasing grade (5 to 1). Accordingly, the sub region 115 that has chips with the highest grade (bin 5) is disposed on the central portion of the substrate 31 of the display 30.

In another embodiment, the substrate also includes two main regions, where multiple chip groups (e.g., bin 5 to bin 1) are arranged in the sub regions 115-112 and half of the sub region 111 of the first main region along the first direction in the order of decreasing grade (5 to 1). Multiple chip groups (e.g., bin 1 to bin 5) are arranged half of the sub region 111 and the sub regions 112-115 of the second main region along the first direction in the order of increasing grade (1 to 5). Referring to FIG. 3, in this embodiment, the central portion of the substrate of the display is set as the sub region 111 that has the lowest grade chips (bin 1).

FIG. 4 is a schematic diagram of a display with gradient mixed micro-LED chips according to yet another embodiment of the present disclosure. The display 40 includes a substrate 41. In this embodiment, the substrate 41 includes a main region 41A. The main region 41A comprises a plurality of sub regions 411 to 41a arranged along a first direction (X-axis direction), and each of the sub-areas 411 to 41a extends along a second direction (Y-axis direction) perpendicular to the first direction. The plurality of micro-LED chips are classified into multiple groups based on their optical or electrical characteristics, such as bin 1 to bin 18, which represent the levels of brightness, wavelength range, or driving current for the three-color (RGB) micro-LED chips. The levels can be arranged in ascending or descending order according to the numerical sequence. The multiple chip groups (e.g., bin 1 to bin 18) are arranged in different sub regions 411 to 41a according to a specific rule.

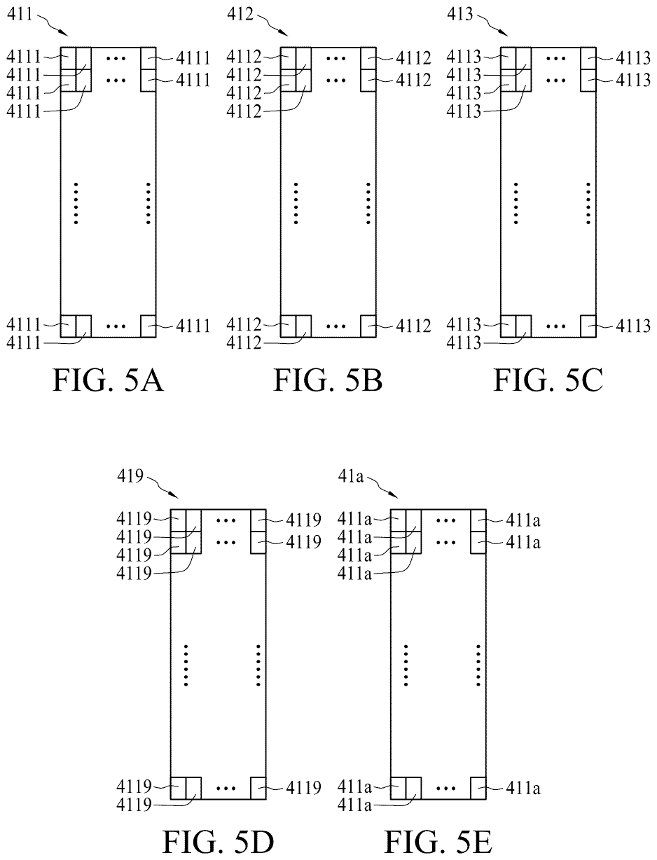

Referring to FIGS. 5A to 5E, as shown in the embodiment of FIG. 4, each of the sub regions 411 to 41a further includes a plurality of child regions 4111 to 411a arranged in a matrix. After the optical and electrical performance tests of the micro-LED chips, they can be classified into multiple groups based on their optical or electrical characteristics (e.g., bin 1 to bin 18). These chip groups are regularly disposed within each of the child regions 4111 to 411a within each of the sub regions 411 to 41a.

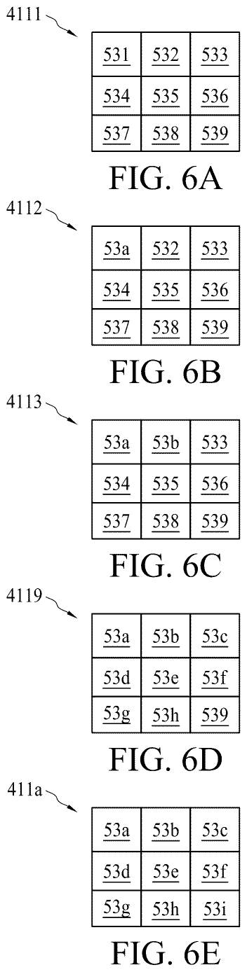

FIGS. 6A to 6E are schematic diagrams showing the regular arrangement of micro-LED chips with various grades within the child regions of each sub region as depicted in FIGS. 5A to 5E. In the sub region 411 closest to the starting point in the first direction (X-axis direction), a part of the micro-LED chips (a part of the grade; the amount of chips is not limited to 9 in this embodiment, it can also be 4, 16, 25, etc.) is arranged such that the grades (531 to 539, and 53a to 53i, i.e., bin 1 to bin 18) of the micro-LED chips in this part increase along the first direction and decrease along the second direction (Y-axis direction), as shown in FIG. 6A. That is, the micro-LED chips in the child regions 4111 are arranged according to the increasing order of their grades, located in the pixel matrix from left to right and from top to bottom.

Furthermore, along the first direction, the child regions 4112 of the next sub region (e.g., sub region 412) adjacent to the previous sub region (e.g., sub region 411) respectively contains another part of the micro-LED chips (in this embodiment, the number of chips is also 9), as shown in FIG. 6B. This part of the micro-LED chips has a later relative maximum grade (53a) and a later relative minimum grade (532). The micro-LED chips in the child regions 4111 of the previous sub region have a former relative maximum grade (539) and a former relative minimum grade (531). Therefore, the later relative maximum grade (53a; i.e., bin 10) is higher than the former relative maximum grade (539; i.e., bin 9) in the previous sub region, and the micro-LED chips with the later relative maximum grade (53a) are disposed in the same locations within the sub regions as the micro-LED chips with the former relative minimum grade (531) in the previous sub region.

According to the foregoing rules, in two adjacent previous and next sub regions, a micro-LED chip with a later relative maximum grade can replace a micro-LED chip with a former relative minimum grade in the previous sub region, thereby generating an arrangement method for the micro-LED chips in the child region of the next sub region. Additionally, the grades and disposition rules of the other micro-LED chips in the previous and next sub regions are the same.

Although the present invention is written with respect to specific embodiments and implementations, various changes and modifications may be suggested to a person having ordinary skill in the art. It is intended that the present disclosure encompasses such changes and modifications that fall within the scope of the appended claims.

What is claimed is:

1. A display with gradient mixed micro-LED chips,
comprising:
a substrate comprising at least one main region, wherein the at least one main region comprises a plurality of sub regions arranged along a first direction, and each of the sub regions extends along a second direction perpendicular to the first direction; and
a plurality of micro-LED chips respectively attributed to a plurality of chip groups according to a plurality of grades in an optical characteristic, wherein the plurality of chip groups are respectively disposed within the plurality of sub regions based on a sequence of the plurality of grades.

2. The display according to claim 1, wherein the at least one main region includes a first main region and a second main region, wherein the plurality of chip groups are arranged in the sub regions of the first main region in an increasing order of the plurality of grades along the first direction and in the sub regions of the second main region in a decreasing order of the plurality of grades along the first direction.

3. The display according to claim 1, wherein the at least one main region includes a first main region and a second main region, wherein the plurality of chip groups are arranged in the plurality of sub regions of the first main region in a decreasing order of the plurality of grades along the first direction, and the plurality of chip groups are arranged in the plurality of sub regions of the second main region in an increasing order of the plurality of grades along the first direction.

4. The display according to claim 2, wherein the first main region and the second main region have the same area and respectively include half of one of the sub regions.

5. The display according to claim 3, wherein the first main region and the second main region have the same area and respectively include half of one of the sub regions.

6. The display according to claim 1, wherein the plurality of sub regions have the same area.

7. The display according to claim 1, wherein the optical characteristic includes brightness or wavelength range.

8. The display according to claim 1, wherein the at least one main region is evenly divided into the plurality of sub regions.

9. The display according to claim 1, wherein the plurality of chip groups in each of the sub regions are of the same grade.

10. A display with a gradient mixed micro-LED chips,
comprising:
a substrate comprising at least one main region, wherein the at least one main region comprises a plurality of sub regions arranged along a first direction, and each of the sub regions extends along a second direction perpendicular to the first direction, and each of the sub regions includes a plurality of child regions arranged in an array; and
a plurality of micro-LED chips respectively attributed to a plurality of chip groups according to a plurality of grades in an optical or electrical characteristic;
wherein in each child region of a first sub region of the plurality of sub regions that is closest to a starting point of the first direction, a part of the micro-LED chips is arranged in a manner such that their grades increase along the first direction and decrease along the second direction;
wherein in each child region of a second sub region adjacent to the first sub region along the first direction, another part of the micro-LED chips is arranged, and the another part includes a latter relative maximum grade and a latter relative minimum grade;
wherein the latter relative maximum grade is greater than the former relative maximum grade; and
wherein the micro-LED chip with the latter relative maximum grade is disposed at an identical location of within a child region of the second sub region as the micro-LED chip with the former relative minimum grade within a corresponding child region of the first sub region.

11. The display according to claim 10, wherein the grades of the other micro-LED chips in the first and second sub regions and a rule for their arrangement are the same.

12. The display according to claim 10, wherein the optical characteristic includes brightness or wavelength range.

13. The display according to claim 10, wherein the electrical characteristic is a drive current.

14. The display according to claim 10, wherein the micro-LED chips in each of the child regions are arranged according to the increasing order of their grades, located in a pixel matrix from left to right and from top to bottom.

15. The display according to claim 10, wherein the plurality of sub regions have the same area.

16. A display with a gradient mixed micro-LED chips,
comprising:
a substrate comprising at least one main region, wherein the at least one main region comprises a plurality of sub regions arranged along a first direction, and each of the sub regions extends along a second direction perpendicular to the first direction, and each of the sub regions includes a plurality of child regions arranged in an array; and
a plurality of micro-LED chips respectively attributed to a plurality of chip groups according to a plurality of grades in an optical or electrical characteristic;
wherein in each first child region of a first sub region of the plurality of sub regions that is closest to a starting point of the first direction, a first set of N micro-LED chips is arranged in a manner such that the first set having grades M+1 to M+N are positioned in ascending grade order along the first direction and in descending grade order along the second direction, wherein M and N are integers;
wherein in each second child region of a second sub region adjacent to the first sub region along the first direction, a second set of N micro-LED chips is arranged in a manner such that the second set has grades M+2 to M+N+1, the micro-LED chips with M+2 to M+N are positioned in ascending grade order along the first direction and in descending grade order along the second direction, and the micro-LED chip with grade M+N+1 within the second child region and the micro-LED chip with grade M+1 within the first child region is disposed at a corresponding location.

17. The display according to claim 16, wherein the optical characteristic includes brightness or wavelength range.

18. The display according to claim 16, wherein the electrical characteristic is a drive current.

19. The display according to claim 16, wherein the at least one main region is evenly divided into the plurality of sub regions.

20. The display according to claim 16, wherein the plurality of sub regions have the same area.
